(19) United States
(12) Patent Application Publication
(10) Pub. No.: US 2008/0217617 A1
(43) Pub. Date: Sep. 11, 2008

(54) Thin Film Transistor, Wiring Board and Methods of Manufacturing the Same

(75) Inventors: Shigetoshi Sugawa, Miyagi (JP); Akihiro Morimoto, Miyagi (JP); Makoto Fujimura, Tokyo (JP); Takeyoshi Katoh, Tokyo (JP); Masahiko Chiba, Aomori (JP); Tomoyo Hirayama, Aomori (JP)

Correspondence Address: BIRCH STEWART KOLASCH & BIRCH, PO BOX 747, FALLS CHURCH, VA, 22040-0747, US

(73) Assignee: ZEON CORPORATION, Tokyo (JP)

(21) Appl. No.: 11/988,388

(22) PCT Filed: Jul. 5, 2006
(86) PCT No.: PCT/JP2006/313382

§ 371 Date: Jan. 7, 2008

(30) Foreign Application Priority Data
Jul. 5, 2005 (JP) 2005-196315

(51) Int. Cl. H01L 29/04; H05K 1/03; H01L 21/336; H05K 3/00

(52) U.S. Cl. 257/59; 257/57; 174/258; 438/151; 29/846; 257/E29.003; 257/E21.411

(57) ABSTRACT

A gate electrode or a gate wiring of a thin-film transistor has a four-layer structure including an adhesive base layer, a catalyst layer, a wiring metal layer, and a wiring metal anti-diffusion layer which are laminated in this order. With this structure, adhesion and flatness are improved. In this case, the adhesive base layer is formed by a resin having a structure capable of coordinating to a metal. Hence, adhesion with an insulating substrate can be improved. Further, the wiring metal anti-diffusion layer is formed on the wiring metal layer, so that diffusion of a wiring metal can be inhibited. Thus, characteristics of the thin-film transistor can be improved.

### TECHNICAL FIELD

This invention relates to an electronic device, such as a thin-film transistor, a wiring board, a display device including a liquid crystal display device, an organic EL display device, and an inorganic EL display device, and a method of manufacturing the same.

### BACKGROUND ART

In general, a display device, such as a liquid crystal display device, an organic EL display device, or an inorganic EL display device, is fabricated by sequentially forming films and patterning the films to form conductive patterns, such as a wiring pattern and an electrode pattern, on a transparent substrate or the like having a flat principal surface. Specifically, on the principal surface of the transparent substrate, a conductive film for forming a wiring necessary for the display device is adhered. The conductive film is selectively etched by using a photolithography technique or the like to form the wiring pattern. Thereafter, an electrode film and various types of films necessary for elements constituting the display device are sequentially formed and patterned in the similar manner. Thus, the display device is produced. By using the similar technique, a thin-film transistor and a wiring board for use in the display device are also produced.

In recent years, there is a strong demand for an increase in size of the display device of the type. In order to form a large-size display device, it is required to form a greater number of display elements on the transparent substrate with high accuracy and to electrically connect these elements to the wiring pattern. In this case, in addition to the wiring pattern, an insulating film, TFT (thin-film transistor) elements, light-emitting elements, and so on are formed in a multi-layered state on the transparent substrate. As a result, level differences are generally formed on the transparent substrate in a stepwise fashion and the wiring pattern is formed across the level differences.

Furthermore, when the display device is increased in size, the wiring pattern itself becomes long. Therefore, it is required to reduce a resistance of the wiring pattern. Patent Document 1 (WO 2004/110117) discloses a technique of reducing a resistance of a wiring for a flat display, such as a liquid crystal display. In Patent Document 1, the wiring is formed on a surface of a transparent substrate and a transparent insulating material having a height equivalent to that of the wiring is formed in contact with the wiring pattern. With this structure, the resistance of the wiring pattern is reduced. Specifically, this document discloses a wiring buried-type substrate having a single-layer wiring portion which is obtained by patterning a transparent resin film on a glass substrate to form a groove and filling the groove with an ink agent containing Cu as a wiring material. The wiring portion is substantially flush with a surface of the above-mentioned film.

Patent Document 1: WO 2004/110117

### DISCLOSURE OF THE INVENTION

### Problem to be Solved by the Invention

Patent Document 1 discloses that characteristics of a display device can be improved by burying the wiring into the groove formed by a resin pattern to form a thick film wiring. However, following a further increase in size of the display device, it is sometimes observed that adhesion between the substrate and an electrode or the wiring and a resultant flatness of the surface of the substrate are insufficient.

It is an object of the present invention to provide an excellent electronic device or the like in which the above-mentioned problem is resolved, and a method of manufacturing the same.

Specifically, it is an object of the present invention to provide a thin-film transistor (TFT) excellent in adhesion and in flatness, a wiring board having the thin-film transistor, and a method of manufacturing the same.

It is another object of the present invention to provide a wiring board which is provided with a wiring pattern excellent in adhesion and which is capable of constructing a large-size display device and a method of manufacturing the same.

It is still another object of the present invention to provide a display device including a thin-film transistor excellent in adhesion and in flatness and a method of manufacturing the same.

It is yet another object of the present invention to provide an electronic device, such as a thin-film transistor, in which a fine pattern can be quickly formed and which is operable at high speed and a method of manufacturing the same.

### Means to Solve the Problem

According to a first aspect of the present invention, there is provided a thin-film transistor having a gate electrode on an insulating substrate, the thin-film transistor at least comprising a semiconductor layer disposed on the gate electrode through a gate insulating film on the side opposite to the insulating substrate and a source electrode and a drain electrode connected to the semiconductor layer, the thin-film transistor being variable in amount of electric current flowing between the source electrode and the drain electrode in response to a current control signal supplied to the gate electrode, wherein the gate electrode comprises an adhesive base layer, a catalyst layer, a wiring metal layer, and a wiring metal anti-diffusion layer which are laminated in this order from the insulating substrate toward the gate insulating film, the adhesive base layer being formed by a resin having a structure capable of coordinating to a metal.

According to a second aspect of the present invention, there is provided the thin-film transistor according to the first aspect, wherein the gate electrode is buried in a groove formed in a planarizing layer generally flush with a surface of the gate electrode.

According to a third aspect of the present invention, there is provided the thin-film transistor according to the second aspect, wherein the insulating substrate is a transparent glass substrate or a transparent resin substrate and the planarizing layer is a transparent resin layer.

According to a fourth aspect of the present invention, there is provided the thin-film transistor according to the first aspect, wherein the catalyst layer is formed only on a portion of the gate electrode.

According to a fifth aspect of the present invention, there is provided the thin-film transistor according to the third aspect, wherein the transparent resin layer includes one or more kinds of resins selected from a group consisting of an acrylic resin, a silicone-based resin, a fluorine-based resin, a polyimide-based resin, a polyolefin-based resin, an alicyclic olefin-based resin, and an epoxy-based resin.

According to a sixth aspect of the present invention, there is provided the thin-film transistor according to the third aspect, wherein the transparent resin layer is formed by a photosensitive resin composition containing an alkali-soluble alicyclic olefin-based resin and a radiation-sensitive component.

According to a seventh aspect of the present invention, there is provided the thin-film transistor according to the first aspect, wherein the resin having a structure capable of coordinating to a metal is obtained by impregnating a resin with a processing agent having a polar group or a heterocyclic compound having a metal coordinating ability.

According to an eighth aspect of the present invention, there is provided the thin-film transistor according to the seventh aspect, wherein the heterocyclic compound has a functional group capable of coordinating to a metal.

According to a ninth aspect of the present invention, there is provided the thin-film transistor according to the seventh aspect, wherein the heterocyclic compound is at least one kind selected from a group consisting of pyrroles, pyrrolines, pyrrolidines, pyrazoles, pyrazolines, pyrazolidines, imidazoles, imidazolines, triazoles, tetrazoles, pyridines, piperidines, pyridazines, pyrimidines, pyrazines, piperazines, triazines, tetrazines, indoles, isoindoles, indazoles, purines, norharmanes, perimidines, quinolines, isoquinolines, cinnolines, quinoxalines, quinazolines, naphthyridines, pteridines, carbazoles, acridines, phenazines, phenanthridines, phenanthrolines, furans, dioxolans, pyrans, dioxanes, benzofurans, isobenzofurans, coumarins, dibenzofurans, flavones, trithianes, thiophenes, benzothiophenes, isobenzothiophenes, dithiins, thianthrenes, thienothiophenes, oxazoles, isoxazoles, oxadiazoles, oxazines, morpholines, thiazoles, isothiazoles, thiadiazoles, thiazines, phenothiazines.

According to a tenth aspect of the present invention, there is provided a wiring board having a wiring on an insulating substrate, wherein the wiring board having a sectional structure including a partial structure comprising an adhesive base layer, a catalyst layer, a wiring metal layer, and a wiring metal anti-diffusion layer which are laminated in this order from the insulating substrate toward a side where the wiring is formed, the adhesive base layer being formed by a resin having a structure capable of coordinating to a metal.

According to an eleventh aspect of the present invention, there is provided the wiring board according to the tenth aspect, wherein the wiring is buried in a groove formed in a planarizing layer generally flush with the wiring.

According to a twelfth aspect of the present invention, there is provided the wiring board according to the eleventh aspect, wherein the insulating substrate is a transparent glass substrate or a transparent resin substrate and the planarizing layer is a transparent resin layer.

According to a thirteenth aspect of the present invention, there is provided the wiring board according to the tenth aspect, wherein the catalyst layer is formed only in the partial structure.

According to a fourteenth aspect of the present invention, there is provided the wiring board according to the twelfth aspect, wherein the transparent resin layer includes one or more kinds of resins selected from a group consisting of an acrylic resin, a silicone-based resin, a fluorine-based resin, a polyimide-based resin, a polyolefin-based resin, an alicyclic olefin-based resin, and an epoxy-based resin.

According to a fifteenth aspect of the present invention, there is provided the wiring board according to the twelfth aspect, wherein the transparent resin layer is formed by a photosensitive resin composition containing an alkali-soluble alicyclic olefin-based resin and a radiation-sensitive component.

According to a sixteenth aspect of the present invention, there is provided a display device manufactured by using the thin-film transistor according to any one of the first through the ninth aspects.

According to a seventeenth aspect of the present invention, there is provided the display device according to the sixteenth aspect, wherein the display device is a liquid crystal display device or an EL display device.

According to an eighteenth aspect of the present invention, there is provided the display device manufactured by using the wiring board according to any one of the tenth through the fifteenth aspects.

According to a nineteenth aspect of the present invention, there is provided the display device according to the eighteenth aspect, wherein the display device is a liquid crystal display device or an EL display device.

According to a twentieth aspect of the present invention, there is provided a method of manufacturing an electronic device, at least including the steps of forming, on an insulating substrate, a nonphotosensitive transparent resin film having a functional group capable of coordinating to a metal at least on its surface; forming a photosensitive resin film; forming a concave portion for burying an electrode or a wiring by patterning the photosensitive resin film; providing a catalyst to the concave portion; heat curing the resin film; and forming a conductive material layer in the concave portion by plating.

According to a twenty-first aspect of the present invention, there is provided the method of manufacturing an electronic device according to the twentieth aspect, wherein the catalyst for use in the catalyst providing step contains copper, silver, palladium, platinum, nickel, zinc, or cobalt.

According to a twenty-second aspect of the present invention, there is provided the method of manufacturing an electronic device according to the twentieth aspect, further including a step of heat-treating the conductive material layer formed in the concave portion by plating.

According to a twenty-third aspect of the present invention, there is provided the method of manufacturing an electronic device according to the twentieth aspect, wherein the heat curing of the photosensitive resin film is carried out in an inert gas atmosphere or a reductive gas atmosphere.

According to a twenty-fourth aspect of the present invention, there is provided the method of manufacturing an electronic device according to the twentieth aspect, wherein the catalyst providing step is carried out by any one of dipping, puddling, vapor-deposition, spraying, coating, and printing.

According to a twenty-fifth aspect of the present invention, there is provided the method of manufacturing an electronic device according to the twentieth aspect, further including a step of forming an anti-diffusion film on a surface of the conductive material layer by CVD or plating.

According to a twenty-sixth aspect of the present invention, there is provided a method of manufacturing an electronic device, at least including the steps of forming a film by using a nonphotosensitive transparent resin on an insulating substrate; carrying out preprocessing on a resultant nonphotosensitive transparent resin layer; forming a photosensitive resin film; forming a concave portion for burying an electrode or a wiring by patterning the photosensitive resin film; heat curing the resin film; providing a catalyst to the concave portion; forming a conductive material layer in the concave portion by plating; and selectively forming a conductive material anti-diffusion film on the conductive material layer.

According to a twenty-seventh aspect of the present invention, there is provided the method of manufacturing an electronic device according to the twenty-sixth aspect, wherein the step of carrying out preprocessing on the nonphotosensitive transparent resin layer includes a step of impregnating the nonphotosensitive transparent resin layer with an adhesion processing agent having a functional group capable of coordinating to a metal.

According to a twenty-eighth aspect of the present invention, there is provided the method of manufacturing an electronic device according to the twenty-seventh aspect, wherein the step of impregnating with the adhesion processing agent is carried out by any one of dipping, puddling, vapor-deposition, spraying, coating, and printing.

According to a twenty-ninth aspect of the present invention, there is provided the method of manufacturing an electronic device according to the twenty-seventh aspect, wherein the step of carrying out preprocessing on the nonphotosensitive transparent resin layer further includes a step of slight-etching a surface of the nonphotosensitive transparent resin layer after the step of impregnating with the adhesion processing agent.

According to a thirtieth aspect of the present invention, there is provided the method of manufacturing an electronic device according to the twenty-seventh aspect, at least including a step of using a silane coupling agent as the adhesion processing agent.

According to a thirty-first aspect of the present invention, there is provided the method of manufacturing an electronic device according to the thirtieth aspect, wherein the silane coupling agent provides a resin surface with a functional group capable of coordinating to a metal.

According to a thirty-second aspect of the present invention, there is provided the method of manufacturing an electronic device according to the thirty-first aspect, wherein the functional group is at least one kind selected from an amino group, a mercapto group, an ureido group, and an isocyanate group.

According to a thirty-third aspect of the present invention, there is provided the method of manufacturing an electronic device according to the twenty-sixth aspect, wherein the step of carrying out preprocessing on the nonphotosensitive transparent resin layer includes a step of oxidizing or roughening a surface of the nonphotosensitive transparent resin layer by using water containing ozone at a concentration not lower than 1 ppm.

According to a thirty-fourth aspect of the present invention, there is provided the method of manufacturing an electronic device according to the thirty-third aspect, wherein the ozone concentration is 5 ppm to 50 ppm.

According to a thirty-fifth aspect of the present invention, there is provided the method of manufacturing an electronic device according to the twenty-sixth aspect, wherein the step of carrying out preprocessing on the nonphotosensitive transparent resin layer includes a step of oxidizing or roughening a surface of the nonphotosensitive transparent resin layer by performing heat treatment, UV treatment, or plasma treatment in a gas containing an oxygen element.

According to a thirty-sixth aspect of the present invention, there is provided the method of manufacturing an electronic device according to the twenty-sixth aspect, wherein the step of carrying out preprocessing on the nonphotosensitive transparent resin layer includes a step of nitriding or roughening a surface of the nonphotosensitive transparent resin layer by performing heat treatment or plasma treatment in a gas containing a nitrogen element.

According to a thirty-seventh aspect of the present invention, there is provided the method of manufacturing an electronic device according to the twenty-sixth aspect, wherein the step of carrying out preprocessing on the nonphotosensitive transparent resin layer includes a step of providing a surface of the nonphotosensitive transparent resin layer with a metal or a functional group capable of coordinating to a metal by performing heat treatment or plasma treatment.

According to a thirty-eighth aspect of the present invention, there is provided the method of manufacturing an electronic device according to the twenty-sixth aspect, wherein the step of carrying out preprocessing on the nonphotosensitive transparent resin layer includes a step of oxidizing or roughening a surface of the nonphotosensitive transparent resin layer by using an oxidizing agent.

According to a thirty-ninth aspect of the present invention, there is provided the method of manufacturing an electronic device according to the twenty-sixth aspect, wherein the step of carrying out preprocessing on the nonphotosensitive transparent resin layer includes a step of nitriding or roughening a surface of the nonphotosensitive transparent resin layer by using a solution containing a nitrogen element.

According to a fortieth aspect of the present invention, there is provided the method of manufacturing an electronic device according to the twenty-sixth aspect, wherein the step of carrying out preprocessing on the nonphotosensitive transparent resin layer includes a step of etching a surface of the nonphotosensitive transparent resin layer.

According to a forty-first aspect of the present invention, there is provided the method of manufacturing an electronic device according to the twenty-sixth aspect, wherein the step of carrying out preprocessing on the nonphotosensitive transparent resin layer includes a step of oxidizing, nitriding, or roughening a surface of the nonphotosensitive transparent resin layer and a step of thereafter impregnating the nonphotosensitive transparent resin layer with an adhesion processing agent having a functional group capable of coordinating to a metal.

According to a forty-second aspect of the present invention, there is provided the method of manufacturing an electronic device according to the twenty-sixth aspect, wherein the step of carrying out preprocessing on the nonphotosensitive transparent resin layer includes a step of introducing a hydroxyl group to a surface of the nonphotosensitive transparent resin layer and a step of condensing an adhesion agent having a functional group capable of coordinating to a metal and a hydroxyl group.

According to a forty-third aspect of the present invention, there is provided the method of manufacturing an electronic device according to the forty-second, wherein the adhesion agent having the functional group capable of coordinating to a metal and a hydroxyl group is selected from silane coupling agents which have a silanol group and a carboxyl group, a sulfonate group, a mercapto group, an amino group, an imino group, an ether group, a ketone group, a thiol group, or an imidazole group or which exhibit a function equivalent to the above-mentioned groups by hydrolysis.

According to a forty-fourth aspect of the present invention, there is provided the method of manufacturing an electronic device according to the forty-second aspect, wherein the step of introducing a hydroxyl group to the surface of the nonphotosensitive transparent resin layer is performed by oxidation.

According to a forty-fifth aspect of the present invention, there is provided the method of manufacturing an electronic device according to the forty-fourth aspect, wherein the step of performing oxidation is carried out by using any one of ozone-added pure water, a mixed aqueous solution containing a sulfuric acid and a hydrogen peroxide solution, and ultraviolet radiation.

According to a forty-sixth aspect of the present invention, there is provided the method of manufacturing an electronic device according to the twenty-seventh aspect, wherein the catalyst for use in the catalyst providing step contains copper, silver, palladium, platinum, nickel, zinc, or cobalt.

According to a forty-seventh aspect of the present invention, there is provided the method of manufacturing an electronic device according to the twenty-seventh aspect, further including a step of heat-treating the conductive material layer formed in the concave portion by plating.

According to a forty-eighth aspect of the present invention, there is provided the method of manufacturing an electronic device according to the twenty-seventh aspect, wherein the heat curing of the photosensitive resin film is carried out in an inert gas atmosphere or in a reductive gas atmosphere.

According to a forty-ninth aspect of the present invention, there is provided the method of manufacturing an electronic device according to the twenty-seventh aspect, wherein the catalyst providing step is carried out by any one of dipping, puddling, vapor-deposition, spraying, coating, and printing.

According to a fiftieth aspect of the present invention, there is provided the method of manufacturing an electronic device according to the twenty-seventh aspect, wherein the anti-diffusion film is formed by electroless plating or electrolysis plating containing a metal selected from Ni, W, Ta, Nb, Co, and Ti, or by chemical vapor deposition using a fluoride gas containing the above-mentioned metal element as a material.

According to a fifty-first aspect of the present invention, there is provided the method of manufacturing an electronic device according to the twenty-seventh aspect, further including a step of nitriding by nitrogen plasma a surface of the anti-diffusion film formed as mentioned above.

According to a fifty-second aspect of the present invention, there is provided the method of manufacturing an electronic device according to any one of the twentieth through the fifty-first aspects, wherein the electronic device is a thin-film transistor or a wiring board.

According to a fifty-third aspect of the present invention, there is provided a method of manufacturing a liquid crystal display device or an EL display device, wherein the display device is formed by using the method according to any one of claims the twentieth through the fifty-first aspects.

### EFFECT OF THE INVENTION

According to the present invention, for example, a photosensitive transparent resin film formed on a transparent substrate is selectively provided with a groove which reaches the transparent substrate. By burying a wiring portion into the groove, it is possible to construct a wiring portion which is relatively thick as compared with a conventional technique. By increasing the thickness, the wiring can be reduced in width. Therefore, in case of a display device, an opening portion can be widened. Further, as a wiring board, a parasitic capacitance of the wiring can be reduced. Therefore, a signal speed during operation can be increased and power consumption can be reduced. On a surface of the transparent substrate at the bottom of a wiring groove or an electrode groove portion formed in the transparent resin film, an adhesive base layer is formed in order to improve adhesion of the wiring. Therefore, even in case of a large-size display-device, it is possible to obtain a highly-reliable wiring or electrode structure. According to the present invention, it is possible to manufacture an electronic device with a wiring or an electrode having excellent surface flatness. Further, in the present invention, an anti-diffusion layer is provided so that, even in case where a gate electrode of a thin-film transistor is formed by copper, copper diffusion can be suppressed. As a result, a thin-film transistor having a less leak current can be constructed. Furthermore, the present invention has an advantage that a fine pattern can be formed accurately.

### BRIEF DESCRIPTION OF THE DRAWING

FIG. 1 is a sectional view showing one example of a structure of a thin-film transistor according to the present invention.

FIG. 2 is a sectional view showing one example of a structure of a conventional thin-film transistor.

FIG. 3 is a sectional view showing one example of a structure of a gate electrode portion constituting the thin-film transistor according to the present invention.

FIG. 4 is a sectional view for describing, along a sequence of steps, one example of a method of manufacturing a thin-film transistor according to the present invention.

FIG. 5 is a sectional view for describing, along a sequence of steps, one example of the method of manufacturing a thin-film transistor according to the present invention.

FIG. 6 is a sectional view for describing, along a sequence of steps, one example of the method of manufacturing a thin-film transistor according to the present invention.

FIG. 7 is a sectional view for describing, along a sequence of steps, one example of the method of manufacturing a thin-film transistor according to the present invention.

FIG. 8 is a sectional view for describing, along a sequence of steps, one example of the method of manufacturing a thin-film transistor according to the present invention.

FIG. 9 is a sectional view for describing, along a sequence of steps, one example of the method of manufacturing a thin-film transistor according to the present invention.

FIG. 10 is a sectional view for describing, along a sequence of steps, one example of the method of manufacturing a thin-film transistor according to the present invention.

FIG. 11 is a sectional view for describing, along a sequence of steps, one example of the method of manufacturing a thin-film transistor according to the present invention.

FIG. 12 is a sectional view for describing, along a sequence of steps, one example of the method of manufacturing a thin-film transistor according to the present invention.

### DESCRIPTION OF REFERENCE NUMERALS

11 glass substrate

12 adhesive base layer

13 transparent resin film

14 catalyst layer

15 wiring metal layer

16 wiring metal anti-diffusion layer

17 gate electrode

18 gate insulating film

19 amorphous silicon film

20 n⁺-type amorphous silicon film

21 semiconductor layer

22 source electrode

23 drain electrode

### BEST MODE FOR EMBODYING THE INVENTION

Embodiments of the present invention will be described with reference to the drawing.

### First Embodiment

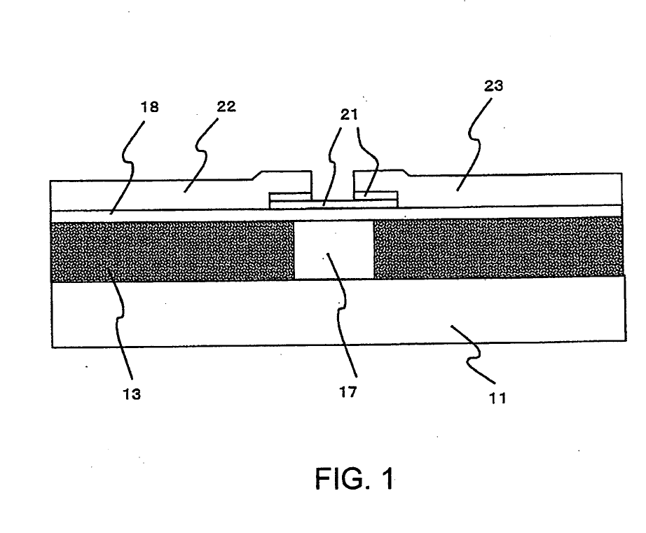

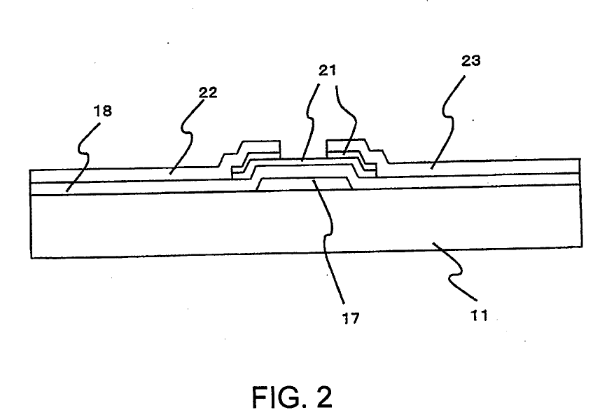

FIG. 1 is a sectional view showing one example of a structure of a thin-film transistor of the present invention. The thin-film transistor comprises an adhesive base layer (not shown) formed on a glass substrate 11 which is an insulating substrate, a transparent resin film 13 formed on the adhesive base layer, a gate electrode 17 which is formed in the transparent resin film 13 so as to reach the adhesive base layer and which is formed to a height generally same as that of the transparent resin film 13, a gate insulating film 18 formed over the transparent resin film 13 and the gate electrode 17, a semiconductor layer 21 formed on the gate electrode 17 via the gate insulating film 18, and a source electrode 22 and a drain electrode 23 which are connected to the semiconductor layer 21. As a comparative example, FIG. 2 shows one example of a sectional structure of a thin-film transistor formed by a known technique.

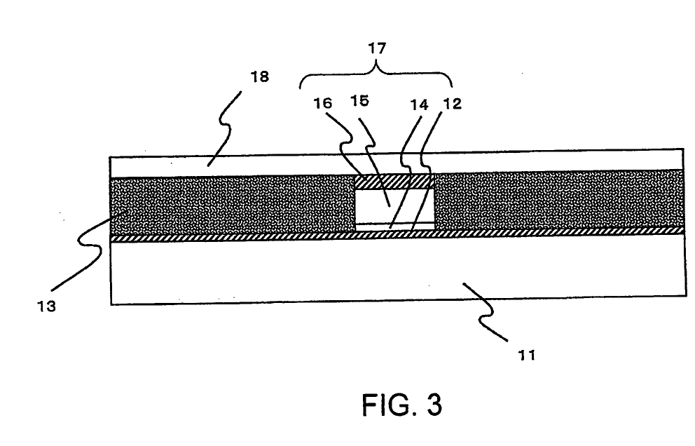

FIG. 3 is a sectional view schematically showing one example of a structure of a gate electrode portion. The gate electrode 17 comprises the adhesive base layer 12, a catalyst layer 14, a wiring metal layer 15, and a wiring metal anti-diffusion layer 16 which are laminated in this order from the insulating substrate (glass substrate 11) toward the gate insulating film 18. The gate electrode is buried in a groove formed in the flat transparent resin film 13 (namely, a planarizing layer). As shown in the figure, the gate electrode 17 is buried in the groove in the transparent resin film 13 so that a surface of the gate electrode is generally flush with the transparent resin film. Therefore, the gate electrode is buried in the groove formed in the planarizing layer generally flush with the surface of the gate electrode so that a TFT can be formed without causing, on the semiconductor layer, a level difference resulting from the gate electrode. Since the surface is flat, effective mobility can be enhanced due to reduction in off-leak current and improvement in film quality. Further, since a buried wiring can be formed by plating, it is possible to lower the cost of production of the display device.

On the other hand, a wiring board of the present invention comprises an insulating substrate and a wiring formed thereon. A sectional structure of the wiring has, as a partial structure, a structure similar to that of the gate electrode in the thin-film transistor of the present invention. Like in the thin-film transistor of the present invention, the wiring is buried in a groove formed in a flat transparent resin film (namely, a planarizing layer). The wiring is buried in the groove in the transparent resin film so that a surface of the wiring is generally flush with the transparent resin film.

Next, as a specific example of a method of manufacturing an electronic device of the present invention, a method of forming a thin-film transistor of the present invention will be described by the use of the drawing. The wiring board of the present invention can similarly be manufactured also.

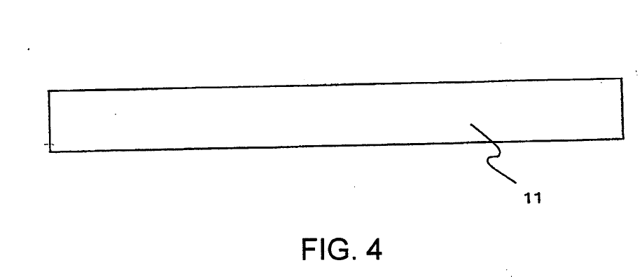

FIGS. 4 through 12 are schematic views showing the method of manufacturing a thin-film transistor of the present invention. First, the glass substrate 11 is prepared as the insulating substrate. As this glass substrate, a large-size substrate adapted to form a large-size screen not smaller than 30 inches may be used. The insulating substrate may be a transparent resin substrate without limitation to the glass. This glass substrate 11 is treated with a 0.5 vol % hydrofluoric acid aqueous solution for 10 seconds, washed with pure water, and dried. Thus, surface contamination is removed by lift-off (FIG. 4).

Next, the glass substrate 11 is treated by, for example, vapor of hexamethyldisilazane. Further, a ring-opening polymer of 8-ethyl-tetracyclo[4.4.0.1^{2,5}.1^{7,10}]-dodeca-3-ene is hydrogenated and then grafted with maleic acid anhydride to obtain an alicyclic olefin polymer having Mn=33,200, Mw=68,300, Tg=170° C., and a maleic acid residue content=25 mol %. 100 weight parts of the alicyclic olefin polymer, 40 weight parts of bisphenol A bis (propylene glycol glycidyl ether) ether, 0.1 weight part of 1-benzyl-2-phenylimidazole, 10 weight parts of liquid polybutadiene are dissolved in a mixed solvent containing 680 weight parts of xylene and 170 weight parts of cyclopentanone to obtain a nonphotosensitive transparent resin solution. The glass substrate is coated with the nonphotosensitive transparent resin solution. Further, the grass substrate is dried at 80° C. for 5 minutes. Then, an aqueous solution adjusted to contain 0.3 vol % of 1-(2-aminoethyl)-2-methylimidazole as an adhesion processing agent is prepared and the glass substrate is dipped in the aqueous solution at 25° C. for 10 minutes. Thereafter, the glass substrate is dipped into another water bath for 1 minute. This is repeatedly carried out three times to wash the glass substrate with water.

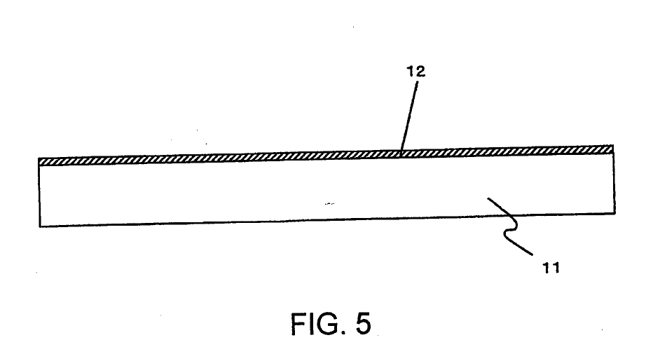

Next, after the excess solution is removed by an air knife, the glass substrate is left in a nitrogen oven kept at 170° C. for 60 minutes. Subsequently, an aqueous solution adjusted to have a permanganic acid concentration of 80 g/liter and a sodium hydroxide concentration of 40 g/liter is prepared and the glass substrate is dipped in the aqueous solution at 80° C. for 5 minutes. Thus, an adhesive base layer 12 having a thickness of 1 μm is formed (FIG. 5).

In the foregoing embodiment described in connection with FIG. 5, (1) the adhesive base layer is formed by coating the insulating substrate with a resin to obtain a resin film and thereafter impregnating the resin film with the adhesion processing agent (for example, a processing agent having a polar group or a heterocyclic compound having a metal coordinating ability, which will later be described). Alternatively, (2) the adhesive base layer may be obtained by coating the insulating substrate with a resin inherently having a structure capable of coordinating to a metal to form a resin film. In the present specification, description “the adhesive base layer is formed by a resin having a structure capable of coordinating to a metal” encompasses the case where the adhesive base layer is formed by either one of the two embodiments mentioned above.

In addition to that mentioned above, the nonphotosensitive transparent resin may be, for example, an epoxy resin, a maleimide resin, a methacrylic resin, an acrylic resin, a diallyl phthalate resin, a triazine resin, an alicyclic olefin polymer except the above, an aromatic polyether polymer, a benzocyclobutene polymer, a cyanate ester polymer, a liquid crystal polymer, polymide and so on. As the nonphotosensitive transparent resin, use is suitably made of a resin inherently having a structure capable of coordinating to a metal, for example, a resin having a functional group capable of coordinating to a metal, which will later be described.

The above-mentioned adhesion processing agent means a compound having a property capable of providing a processing object with a structure capable of coordinating to a metal. For example, in the foregoing embodiment described in connection with FIG. 5, the nonphotosensitive transparent resin film is impregnated with the adhesion processing agent so that an amino group and an imidazole group are substantially located on a surface of the adhesive base layer 12 to obtain a structure which allows easy coordination of a metal complex. As the adhesion processing agent exhibiting such an effect, a processing agent having a functional group capable of coordinating to a metal is preferable. Suitably, a processing agent having a polar group, such as an amino group, a hydroxyl group, a thiol group, or a disulfide group, a heterocyclic compound having a metal-coordinating ability, or the like may be selected. Particularly, a heterocyclic compound containing nitrogen atoms, oxygen atoms, or sulfur atoms is preferable. Especially, the heterocyclic compound containing nitrogen atoms is preferable.

As the above-mentioned processing agent, for example, a silane coupling agent, such as 3-(aminopropyl)triethoxysilane, which generates a silanol group by hydrolysis and which has an amino group or the like is suitable. In this case, the above-mentioned impregnation, surface coating, condensation, and so on may suitably be used.

For example, a processing agent having a polar group as the above-mentioned adhesion processing agent may be chain-type tertiary amine compounds such as benzyldimethylamine, triethanolamine, triethylamine, tributylamine, tribenzylamine, and dimethyl formaldehyde; imidazoles: imidazole; imidazoles having a thiol group, such as 2-mercaptoimidazole, 2-mercaptomethyl benzoimidazole, 2-(2-mercaptoethyl)-benzoimidazole, and 2-mercapto-4-azabenzoimidazole; imidazole dithiocarboxylic acids such as imidazole-4-dithiocarboxylic acid, 2-methylimidazole-4-dithiocarboxylic acid, 2-ethylimidazole-4-dithiocarboxylic acid, 2-isopropylimidazole-4-dithiocarboxylic acid, 2-n-butylimidazole-4-dithiocarboxylic acid, 2-phenylimidazole-4-dithiocarboxylic acid, 4-methylimidazole-5-dithiocarboxylic acid, 2-phenyl-4-methylimidazole-5-dithiocarboxylic acid, 2-ethylimidazole-4-dichiocarboxylic acid, and 2-n-undecylimidazole-4-dithiocarboxylic acid; imidazoles having a carboxyl group, such as imidazole-2-carboxylic acid, imidazole-4-carboxylic acid, 2-methylimidazole-4-carboxylic acid, 2-phenylimidazole-4-carboxylic acid, 2-methyl-4-methylimidazole-5-carboxylic acid, 2-(2-carboxyethyl)-benzoimidazole, and imidazole-2-carboxyamide; imidazoles having an amino group, such as 1-(2-aminoethyl)-2-methylimidazole, 1-(2-aminoethyl)-ethylimidazole, 2-aminoimidazole sulfate, and 2-(2-aminoethyl)-benzoimidazole; imidazoles having a cyano group, such as 2-cyanoimidazole, 4-cyanoimidazole, 4-methyl-5-cyanoimidazole, 2-methyl-5-cyanoimidazole, 2-phenyl-5-cyanoimidazole, 4-cyanomethylimidazole, 1-(2-cyanoethyl)-2-ethylimidazole, 1-(2-cyanoethyl)-2-ethyl-4-methylimidazole, 1-(2-cyanoethyl)-2-n-undecylimidazole, and 1-(2-cyanoethyl)-2-phenylimidazole;

imidazoles having other groups such as 2-methylimidazole, 2-ethylimidazole, 2-isopropylimidazole, 2-n-propylimidazole, 2-n-butylimidazole, 2-phenylimidazole, 2-n-undecylimidazole, 2-n-heptadecylimidazole, 1,2-dimethylimidazole, 1-methyl-2-ethylimidazole, 1-benzyl-2-methylimidazole, 1-benzyl-2-ethylimidazole, 1-benzyl-2-phenylimidazole, 4-methylimidazole, 2,4-dimethylimidazole, 2-ethyl-4-methylimidazole, 2-n-butyl-4-methylimidazole, 2-phenyl-4-methylimidazole, 1-methylimidazole, 2-n-butyl-4-chloro-5-formylimidazole, 2-formylimidazole, 4-formylimidazole, 2-methyl-4-formylimidazole, 2-n-butyl-4-formylimidazole, 2-phenyl-4-formylimidazole, 4-methyl-5-formylimidazole, 2-ethyl-4-methyl-5-formylimidazole, 2-phenyl-4-methyl-5-formylimidazole, 2-methyl-4,5-diformylimidazole, 2-ethyl-4,5-diformylimidazole, 2-isopropyl-4,5-diformylimidazole, 2-n-propyl-4,5-diformylimidazole, 2-n-butyl-4,5-diformylimidazole, 2-n-undecyl-4,5-diformylimidazole, 2-nitroimidazole, 1-{2-hydroxy-3-(3-trimetoxysilylpropyloxy)}propylimidazole, 4-hydroxymethylimidazole hydrochloride, 2-hydroxymethylimidazole hydrochloride, 2-methyl-4,5-dihydroxymethylimidazole, 2-ethyl-4,5-dihydroxymethylimidazole, 2-isopropyl-4,5-dihydroxymethylimidazole, 2-n-propyl-4,5-dihydroxymethylimidazole, 2-n-butyl-4,5-dihydroxymethylimidazole, 2-phenyl-4,5-dihydroxymethylimidazole, 2-n-undecyl-4,5-dihydroxymethylimidazole, benzoimidazole, benzoimidazole, 2-hydroxymethylbenzoimidazole, 2-chloromethylbenzoimidazole, 1-{3-(3-trimethoxysilylpropyloxy)}proplimidazole, 4-thiocarbamoylimidazole, 2-methyl-4-thiocarbamoylimidazole, 4-methyl-5-thiocarbamoylimidazole, 2-ethyl-4-methyl-5-thiocarbamoylimidazole, 2-phenyl-4-thiocarbamoylimidazole, 2-(2′-methylimidazolyl-4′)-benzoimidazole, 2-(2′-phenylimidazolyl-4′)-benzoimidazole, 4-azabenzoimidazole, 2-hydroxy-4-azabenzoimidazole, and 2-hydroxymethyl-4-azabenzoimidazole; etc.

pyrazoles: pyrazole; pyrazoles having a carboxyl group, such as 4-carboxymethylpyrazole, 5-carboxymethylpyrazole, 1-methyl-4-carboxymethylpyrazole, 1-isopropyl-4-carboxymethylpyrazole, 1-benzyl-4-carboxymethylpyrazole, 1-methyl-5-carboxymethylpyrazole, 1-isopropyl-5-carboxymethylpyrazole, 1-benzyl-5-carboxymethylpyrazole, 1,3-dimethyl-4-carboxymethylpryazole, 1-isopropyl-3-methyl-4-carboxymethylpyrazole, 1-benzyl-3-methyl-4-carboxymethylpyrazole, 1,3-dimethyl-5-carboxymethylpryazole, 1-isopropyl-3-methyl-5-carboxymethylpyrazole, 1-benzyl-3-methyl-5-carboxymethylpyrazole, 1,5-dimethyl-4-carboxylmethylprazole, 1-methyl-4-carboxymethyl-5-hydroxypyrazole, 1-methyl-4-chloro-5-carboxymethylpyrazole, 1-methyl-4,5-dicarboxymethylpyrazole, 1-methyl-4-cyano-5-carboxymethylpyrazole, 1-methyl-4-carboxymethyl-5-chloropyrazole, 1-isopropyl-4-carboxymethyl-5-methylpyrazole, 1-isopropyl-4-carboxymethyl-5-hydroxypyrazole, 1-isopropyl-4-choro-5-carboxymethylpyrazole, 1-isopropy-4,5-dicarboxymethylpyrazole, 1-isopropyl-4-dicarboxymethy-5-chloropyrazole, 1-benzyl-4-carboxymethyl-5-hydroxypyrazole, 1-benzyl-4-carboxymethyl-5-methylpyrazole, 1-benzyl-4-chloro-5-carboxymethylpyrazole, 1-benzyl-4,5-dicarboxymethylpyrazole, 1-benzyl-4-carboxymethyl-5-chloropyrazole, 3-methyl-4-carboxymethyl-5-hydroxypyrazole, 3,5-dimethyl-4-carboxymethylpyrazole, 3-methyl-4-chloro-5-carboxymethylpyrazole, 3-methyl-4,5-dicarboxymethylpyrazole, 3-methyl-4-dicarboxymethyl-5-chloropyrazole, 1,3,5-trimethyl-4-carboxymethylpyrazole, 1-benzyl-3,5-dimethyl-4-carboxymethylpyrazole, 1,3-dimethyl-4-carboxymethyl-5-hydroxypyrazole, 1,3-dimethyl-4-chloro-5-carboxymethylpyrazole, and 1,3-dimethyl-4,5-dicarboxymethylpyrazole.

pyrazoles having a cyano group, such as 4-cyanopyrazole, 1-methyl-4-cyanopyrazole, 1-isopropyl-4-cyanopyrazole, 1-benzyl-4-cyanopyrazole, 1,3-dimethyl-4-cyanopyrazole, 1-isopropyl-3-methyl-4-cyanopyrazole, 1-benzyl-3-methyl-4-cyanopyrazole, 1,5-dimethyl-4-cyanopyrazole, 1-isopropyl-4-cyano-5-methylpyrazole, 1-isopropyl-4-cyano-5-hydroxypyrazole, 1-isopropyl-4-cyano-5-chloropyrazole, 1-benzyl-4-cyano-5-methylpyrazole, 1-benzyl-4-cyano-5-hydroxypyrazole, 1-benzyl-4-cyano-5-chloropyrazole, 3,5-dimethyl-4-cyanopyrazole, 3-methyl-4-cyano-5-hydroxypyrazole, 3-methyl-4-cyano-5-chloropyrazole, 1,3,5-trimethyl-4-cyanopyrazole, 1-benzyl-3,5-dimethyl-4-cyanopyrazole, and 1,3-dimethyl-4-cyano-5-hydroxypyrazole; pyrazoles having an amino group, such as 5-aminopyrazole, 1-methyl-5-aminopyrazole, 1-isopropyl-5-aminopyrazole, 1-benzyl-5-aminopyrazole, 1,3-dimethyl-5-aminopyrazole, 1-isopropyl-3-methyl-5-aminopyrazole, 1-benzyl-3-methyl-5-aminopyrazole, 1-methyl-4-chloro-5-aminopyrazole, 1-methyl-4-cyano-5-aminopyrazole, 1-isopropyl-4-chloro-5-aminopyrazole, 3-methyl-4-chloro-5-aminopyrazole, 1-benzyl-4-chloro-5-aminopyrazole, and 1,3-dimethyl-4-chloro-5-aminopyrazole;

pyrazoles having any two or more groups selected from amino groups, carboxyl groups, and cyano groups, such as 1-methyl-4-carboxymethyl-5-aminopyrazole, 1-isopropyl-4-carboxymethyl-5-aminopyrazole, 1-benzyl-4-carboxymethyl-5-aminopyrazole, 3-methyl-4-carboxymethyl-5-aminopyrazole, 1,3-dimethyl-4-carboxymethyl-5-aminopyrazole, 1-isopropyl-4-cyano-5-aminopyrazole, 1-benzyl-4-cyano-5-aminopyrazole, 3-methyl-4-cyano-5-aminopyrazole, 1,3-dimethyl-4-cyano-5-aminopyrazole, 1-isopropyl-4-cyano-5-carboxymethylpyrazole, 1-benzyl-4-cyano-5-carboxymethylpyrazole, 3-methyl-4-cyano-5-carboxymethylpyrazole, and 1,3-dimethyl-4-cyano-5-carboxymethylpyrazole;

pyrazoles having other groups, such as 1-methylpyrazole, 1-isopropylpyrazole, 1-benzylpyrazole, 3-methylpyrazole, 5-methylpyrazole, 1,3-dimethylpyrazole, 4-chloropyrazole, 5-hydroxypyrazole, 5-chloropyrazole, 1-methyl-4-chloropyrazole, 1-isopropyl-4-chloropyrazole, 1,5-dimethylpyrazole, 1-methyl-5-hydroxypyrazole, 1-methyl-5-chloropyrazole, 1-isopropyl-5-methylpyrazole, 1-isopropyl-5-hydroxypyrazole, 1-isopropyl-5-chloropyrazole, 1-benzyl-5-methylpyrazole, 1-benzyl-5-hydroxypyrazole, 1-benzyl-5-chloropyrazole, 1,3-dimethyl-4-chloropyrazole, 1-benzyl-3-methyl-4-chloropyrazole, 1,3,5-trimethylpyrazole, 1,3-dimethyl-5-hydroxypyrazole, 1,3-dimethyl-5-chloropyrazole, 1-isopropyl-3-methyl-5-hydroxypyrazole, 1-benzyl-3,5-dimethylpyrazole, 1-benzyl-3-methyl-5-ethylpyrazole, 1-methyl-4-cyano-5-hydroxypyrazole, 1-methyl-4,5-dichloropyrazole, 1-methyl-4-cyano-5-chloropyrazole, 1-isopropyl-4-chloro-5-methylpyrazole, 1-isopropyl-4-chloro-5-hydroxypyrazole, 1-isopropyl-4,5-dichloropyrazole, 1-benzyl-4-chloro-5-methylpyrazole, 1-benzyl-4-chloro-5-hydroxypyrazole, 1-benzyl-4,5-dichloropyrazole, 3,5-dimethyl-4-chloropyrazole, 3-methyl-4-chloro-5-hydroxypyrazole, 3-methyl-4,5-dichloropyrazole, 1,3,5-trimethyl-4-chloropyrazole, 1-isopropyl-3,5-dimethyl-4-chloropyrazole, and 1,3-dimethyl-4-chloro-5-hydroxypyrazole; etc.

triazoles: 1,2,4-triazole; triazoles having an amino group, such as 1-amino-1,2,4-triazole, 2-amino-1,2,4-triazole, 1,2-diamino-1,2,4-triazole, 1-amino-2-hydroxy-1,2,4-triazole, 2,5-diamino-1,2,4-triazole, 2-amino-5-hydroxy-1,2,4-triazole, 1,2,5-triamino-1,2,4-triazole, and 1,2-diamino-5-hydroxy-1,2,4-triazole; triazoles having a thiol group, such as 1-mercapto-1,2,4-triazole and 2-mercapto-1,2,4-triazole; triazoles having any two or more groups selected from amino groups, thiol groups, and carboxyl groups, such as 1-amino-2-mercapto-1,2,4-triazole, 1-mercapto-2-amino-1,2,4-triazole, 2-amino-5-mercapto-1,2,4-triazole, 1,2-diamino-5-mercaptotriazole, 1-mercapto-2,5-diamino-1,2,4-triazole, 1-mercapto-2-amino-5-mercapto-1,2,4-triazole, 1-mercapto-2-amino-5-hydroxy-1,2,4-triazole, 1,5-dimercapto-2-amino-1,2,4-triazole, and 3-amino-1,2,4-triazole-5-carboxylic acid; triazoles having other groups, such as 2-hydroxy-1,2,4-triazole; etc. triazines: triazines having an amino group, such as 2-aminotriazine, 2,4-diaminotriazine, and 2,4-diamino-6-(6-(2-(2methyl-1-imidazolyl)ethyl)triazine; triazines having a thiol group, such as 2-anilino-4,6-dimercapto-s-triazine, 2-morpholyl-4,6-dimercapto-s-triazine, 2-monolauryl-4,6-dimercapto-s-triazine, 2,4,6-trimercapto-s-triazine, 2,4,6-trimercapto-s-triazine-monosodium salt, 2,4,6-trimercapto-s-triazine-trisodium salt; triazines having an amino group and a thiol group, such as 2-dibutylamino-4,6-dimercapto-s-triazine; etc.

These processing agents having a polar group may be used alone or as a mixture of two or more kinds.

As the above-mentioned heterocyclic compound, use may also be made of imidazoles such as imidazole, 2-methylimidazole, 2-ethyl-4-methylimidazole, 2-mercaptomethylbenzoimidazole, 2-ethylimidazole-4-dithiocarboxylic, acid, 2-methylimidazole-4-carboxylic acid, 1-(2-aminoethyl)-2-methylimidazole, 1-(2-cyanoethyl)-2-methylimidazole, 2-phenyl-4,5-dihydroxymethylimidazole, benzoimidazole, and 2-ethyl-4-thiocarbamoylimidazole; pyrazoles such as pyrazole and 3-amino-4-cyano-pyrazole; triazoles such as 1,2,4-triazole, 2-amino-1,2,4-triazole, 1,2-diamino-1,2,4-triazole, and 1-mercapto-1,2,4-triazole; triazines such as 2-aminotriazine, 2,4-diamino-6-(6-(2-(2methyl-1-imidazolyl)ethyl)triazine, and 2,4,6-trimercapto-s-triazine-trisodium salt; etc. Besides, the heterocyclic compound may be a compound having a functional group capable of coordinating to a metal. For example, a compound having a functional group capable of coordinating to a metal, such as an amino group, a thiol group, a carboxyl group, or a cyano group is suitable. The heterocyclic compound having a functional group coordinatable to a metal is preferable in that higher pattern adhesion is provided As a heterocyclic compound containing an oxygen atom, a sulfur atom, or a nitrogen atom, use may be made of pyrroles, pyrrolines, pyrrolidines, pyrazoles, pyrazolines, pyrazolidines, imidazoles, imidazolines, triazoles, tetrazoles, pyridines, piperidines, pyridazines, pyrimidines, pyrazines, piperazines, triazines, tetrazines, indoles, isoindoles, indazoles, purines, norharmanes, perimidines, quinolines, isoquinolines, cinnolines, quinoxalines,quinazolines, naphthyridines, pteridines, carbazoles, acridines, phenazines, phenanthridines, phenanthrolines, furans, dioxolans, pyrans, dioxanes, benzofurans, isobenzofurans, coumarins, dibenzofurans, flavones, trithianes, thiophenes, benzothiophenes, isobenzothiophenes, dithiins, thianthrenes, thienothiophenes, oxazoles, isoxazoles, oxadiazoles, oxazines, morpholines, thiazoles, isothiazoles, thiadiazoles, thiazines, phenothiazines, etc.

These heterocyclic compounds may be used alone or as a mixture of two or more kinds.

Among others, heterocyclic compounds described in Japanese Unexamined Patent Application Publication (JP-A) No. 2003-158373 may suitably be used because these compounds react with components in a photosensitive resin composition which will later be described and have an effect that a wiring metal layer (conductive material layer) to be formed thereafter is hardly peeled off.

In the embodiment (1) mentioned above, the method of impregnating the resin film with the adhesion processing agent is not particularly limited. Use may be made of various known methods, such as puddling, vapor-deposition, spraying, coating, and printing, in addition to dipping. In the method of the present invention, on the adhesive base layer formed after impregnation with the adhesion processing agent, a photosensitive resin film is formed. If desired, before formation of the photosensitive resin film, a surface of the adhesive base layer (for example, a nonphotosensitive transparent resin layer) may be subjected to slight etching.

Without using a resin, the adhesive base layer 12 may be formed by the above-mentioned adhesion processing agent itself in place of the resin having a structure capable of coordinating to a metal.

Further, the adhesive base layer may be formed as follows. After a resin base layer is formed on the insulating substrate by using spin-coating, slit-coating, doctor blade, roll-coating, or the like, the resin film is directly nitrided by using a liquid containing electron-releasing nitrogen atoms, such as ammonia, or using a gas containing nitrogen atoms, such as ammonia or nitrogen molecules, and radicalized by plasma treatment to thereby introduce an amino group having a metal coordinating ability.

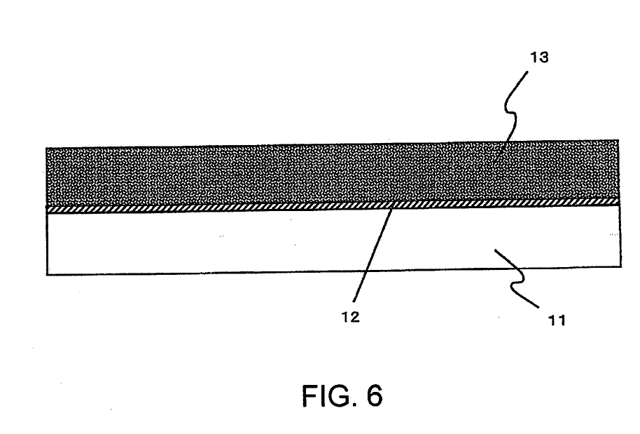

Next, the entire surface of the adhesive base layer 12 formed by the above-mentioned process is coated with, for example, a positive photoresist liquid by using a spinner. On a hot plate, prebaking is carried out by heating at 100° C. for 120 seconds. As a result, the photosensitive transparent resin film 13 having a thickness of 2 μm is formed (FIG. 6). As the positive photoresist mentioned above, for example, use is made of a photosensitive resin composition containing an alkali-soluble alicyclic olefin-based resin and a radiation-sensitive component, which is described in Japanese Unexamined Patent Application Publication (JP-A) No. 2002-296780.

Herein, the alicyclic olefin-based resin is formed by polymerizing cyclic olefin monomers, i.e., olefin monomers having a cyclic structure and is a polymer having a monomer unit as a structural unit. The cyclic structure of the cyclic olefin monomer may be monocyclic or polycyclic (condensed polycyclic, bridged cyclic, combinational polycyclic, and so on). There is no special limit on the number of carbon atoms constituting one unit of the cyclic structure. However, since various characteristics including mechanical strength, heat resistance, and formability are highly balanced, the number of carbon atoms is generally 4 to 30, preferably 5 to 20, more preferably 5 to 15. The alicyclic olefin-based resin may have, as a structural unit, a monomer unit other than the cyclic olefin monomer.

As the alicyclic olefin-based resin, those having a polar group are suitable. A rate of the polar group existing in the resin is not specially limited and may be appropriately selected depending upon the purpose.

As the above-mentioned polar group, use may be made of one or more groups selected from, for example, a group consisting of a carboxyl group (hydroxycarbonyl group), an alkoxycarbonyl group, a dicarboxylic anhydride group (carbonyl oxycarbonyl group), a hydroxyl group, a nitrile group, an epoxy group, an oxetanyl group, and an imide group (hereinbelow, these groups are collectively called “particular polar groups”).

As an example of the particular polar group which is the hydroxyl group, use may be made of a substitute group including a phenolic hydroxyl group, such as a hydroxyphenyl group and a hydroxyphenylalkyl group; a substitute group including an alcoholic hydroxyl group, such as a hydroxyalkyl group, a hydroxyalkoxy group, and a hydroxyalkoxycarbonyl group. A hydroxymethoxy group, a hydroxyethoxy group, or the like are preferable.

As an example of the particular polar group which is the imide group, an N-phenyl dicarboxy imide group or the like may be used.

The alicyclic olefin-based resin may have only one kind of or two or more kinds of the above-mentioned particular polar groups. In particular, it is preferable to combine two or more kinds. Especially, a combination of the carboxyl group and the imide group is preferable.

As the cyclic olefin monomer having a polar group, use may be made of, for example, cyclic olefin monomers having one carboxyl group, such as 5-hydroxycarbonyl-bicyclo[2.2.1]hept-2-ene, 5-methyl-5-hydroxycarbonyl-bicyclo[2.2.1]hept-2-ene, 5-carboxymethyl-5-hydroxycarbonyl-bicyclo[2.2.1]hept-2-ene, 8-methyl-8-hydroxycarbonyl-tetracyclo[4.4.0.1^{2,5}.1^{7,10}]dodeca-3-ene, and 8-carboxymethyl-8-hydroxycarbonyl-tetracyclo[4.4.0.1^{2,5}.1^{7,10}]dodeca-3-ene; cyclic olefin monomers having two carboxyl groups, such as 5-exo-6-endo-dihydroxycarbonyl-bicyclo[2.2.1]hept-2-ene, 8-exo-9-endo-dihyrdoxycarbonyl-tetracylco[4.4.0.1^{2,5}.1^{7,10}]dodeca-3-ene, bicyclo[2.2.1]hept-2-ene-5,6-dicarboxylic anhydride, tetracyclo[4.4.0.1^{2,5}.1^{7,10}]dodeca-3-ene-8,9-dicarboxylic anhydride, and hexacyclo[6.6.1.1^{3,6}.1^{10,13}.0^{2,7}.0^{9,14}]heptadeca-4-ene-11,12-dicarboxylic anhydride; cyclic olefin monomers having one hydroxyphenyl group, such as 5-(4-hydroxyphenyl)bicyclo[2.2.1]hept-2-ene, 5-methyl-5-(4-hydroxyphenyl)bicyclo[2.2.1]hept-2-ene, 5-carboxymethyl-5-(4-hydroxyphenyl)bicyclo[2.2.1]hept-2-ene, 8-methyl-8-(4-hydroxyphenyl)tetracyclo[4.4.0.1^{2,5}.1^{7,10}]dodeca-3-ene, and 8-carboxymethyl-8-(4-hydroxyphenyl)tetracylco[4.4.0.1^{2,5}.1^{7,10}]dodeca-3-ene; cyclic olefin monomers containing an N-substitute imide group, such as N-(4-phenyl)-(5-norbornene-2,3-dicarboxyimide); etc.

A molecular weight of the alicyclic olefin-based resin for use in the present invention is appropriately selected depending upon the intended purpose of use. A weight-average molecular weight (Mw) in terms of equivalent polystyrene molecular weight, measured by the gel permeation chromatography (GPC) using tetrahydrofuran (THF) as a solvent, is in a range of generally 3,000 to 500,000, preferably 3,500 to 100,000, more preferably 4,000 to 50,000.

As an organic material for forming the transparent resin film, use may be made of a transparent resin selected from a group consisting of an acrylic resin, a silicone-based resin, a fluorine-based resin, a polyimide-based resin, a polyolefin-based resin, an alicyclic olefin-based resin, and an epoxy-based resin. From the standpoint of facilitating subsequent processes, it is advantageous to form the transparent resin film by using a photosensitive resin composition.

In this case, as the photosensitive resin composition suitably used to form the transparent resin film 11, use may be made of, for example, a composition containing: alicyclic olefin-based resin such as alkali-soluble alicyclic olefin-based resin having a polar group; cross-linking agents, such as polyfunctional epoxy compounds, having two or more epoxy groups, preferably three or more epoxy groups, such as bisphenol A epoxy resin, bisphenol F epoxy resin, phenol novolak epoxy resin, cresol novolak epoxy resin, polyphenol epoxy resin, cyclic aliphatic epoxy resin, aliphatic glycidyl ether, and epoxyacrylate polymer; and a photo-acid-generating agent (radiation-sensitive component) such as an ester compound of (a) quinonediazide sulfonyl halide, such as 1,2-naphthoquinonediazide-4-sulfonyl chloride, 1,2-naphthoquinonediazide-4-sulfonyl chloride, and 1,2-benzoquinonediazide-5-sulfonyl chloride, and (b) a compound having a phenolic hydroxyl group, such as 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol. Such composition may contain, for example, colloidal silica as inorganic fine particles. The photosensitive resin composition used in this invention may be a positive type or a negative type.

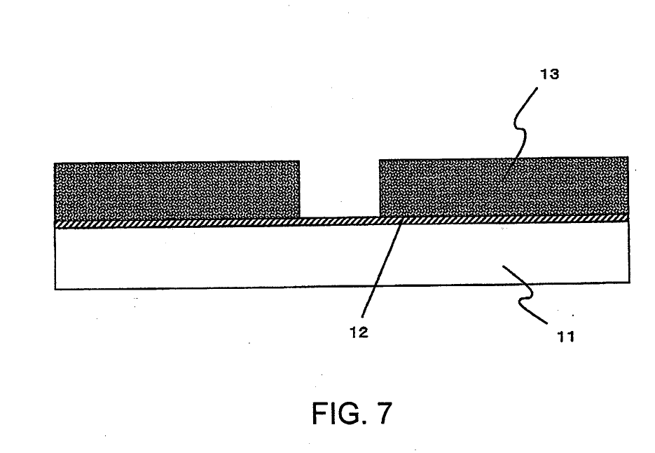

After the transparent resin film 13 is formed as shown in FIG. 6, a mixed light of g, h, and i rays is selectively irradiated onto the transparent resin film 13 through a mask pattern by the use of a mask aligner. Subsequently, development is performed for 90 seconds using a 0.3 wt % tetramethylammonium hydroxide aqueous solution and then rinsing is carried out for 60 seconds using pure water. Thus, a groove (concave portion for burying a gate electrode) which has a predetermined pattern and which reaches a surface of the glass substrate 11 is formed on the glass substrate 11. Thereafter, heat treatment is carried out in a nitrogen atmosphere at 230° C. for 60 minutes to cure the transparent resin film 13 (FIG. 7). The heat treatment (heat cure) of the transparent resin film may be carried out after a subsequent process of providing a catalyst to the concave portion. Further, the heat treatment may be carried out in a reductive gas atmosphere other than in an inert gas atmosphere, such as the nitrogen atmosphere, as mentioned above.

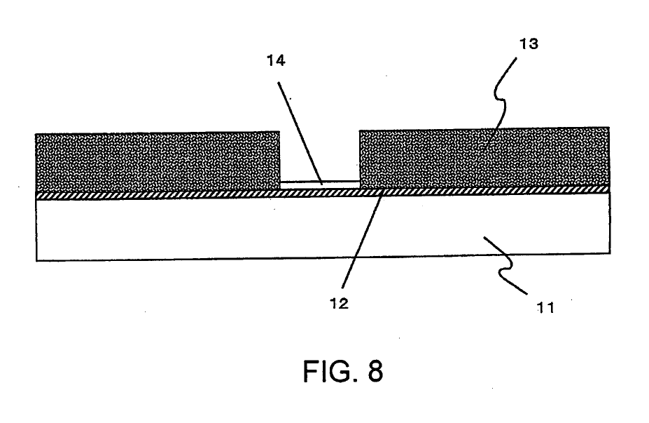

Then, the substrate obtained as mentioned above is dipped in a palladium chloride-hydrochloric acid aqueous solution (0.005 vol % palladium chloride and 0.01 vol % hydrochloric acid) at room temperature for 3 minutes, treated with a reducing agent (Reducer MAB-2 manufactured by C. Uyemura & Co., Ltd.), and washed with water. Thus, the inside of the groove (concave portion) formed as mentioned above is selectively provided with the palladium catalyst layer 14 (having a thickness of 10 to 50 nm) (FIG. 8). The palladium catalyst layer 14 is not required to be a continuous film and may comprise fine palladium particles deposited densely to the extent that formation of a plating film to be subsequently formed is not inhibited. The catalyst layer is not particularly limited and may be similarly formed by using copper, silver, platinum, nickel, zinc, or cobalt other than palladium. Further, a method of providing the concave portion with a catalyst is not particularly limited. For example, use may be made of various known methods, such as puddling, vapor-deposition, spraying, coating, and printing in addition to dipping. The catalyst layer is formed as mentioned above and, consequently, the catalyst layer is formed only in the gate electrode portion. On the other hand, in case where the wiring board is produced, the catalyst layer is formed only in the above-mentioned partial structure.

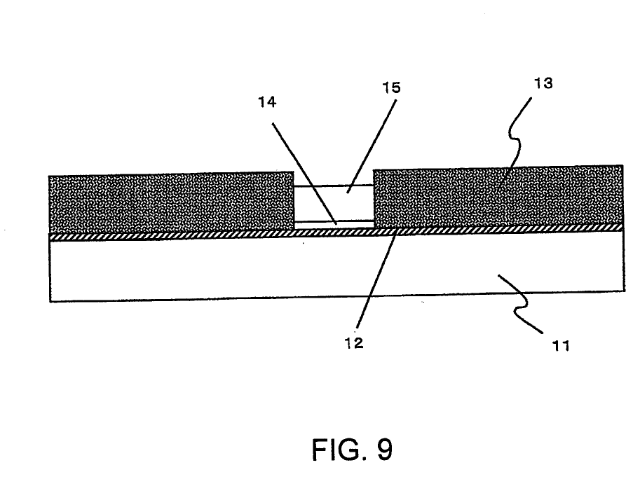

The substrate thus obtained is dipped into, for example, an electroless copper plating solution (PGT manufactured by C. Uyemura & Co., Ltd.) to selectively form the copper wiring metal layer 15 (having a thickness of 1.9 μm) in the groove mentioned above (FIG. 9). Preferably, this process is completed at a position where the copper wiring metal layer 15 is lower than a surface height of the transparent resin film 13 by a film thickness of an anti-diffusion film to be subsequently formed. The wiring metal layer 15 may be formed by an opaque metal, such as aluminum or tungsten, in addition to copper, or may be formed also by a transparent conductive film, for example, ITO. The wiring metal layer is thus formed and, after the formation of the wiring metal layer, the layer may be subjected to heat treatment if desired. The heat treatment may be carried out, for example, in a manner similar to the heat treatment of the transparent resin film.

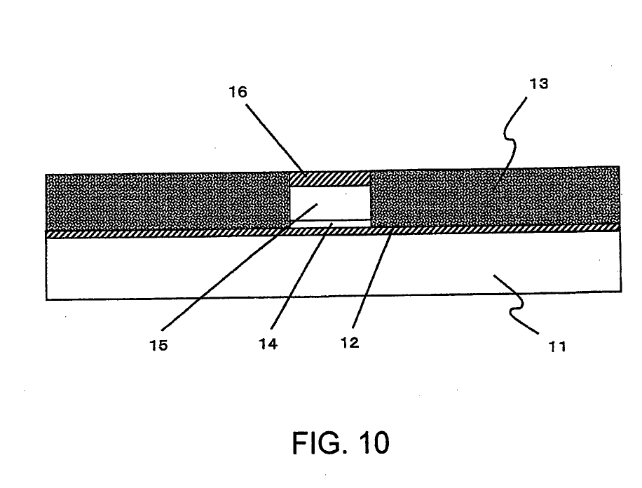

In the state of FIG. 9, washing with pure water and drying by N₂ blow are carried out. Thereafter, the anti-diffusion film is formed by electroless Ni plating, electroless Ni—P plating, electroless Ni—B plating, electrolysis Ni plating, electroless cobalt-tungsten alloy plating, or the like with the deposited Cu film used as a base. As the anti-diffusion film, use may be made of a metal selected from Ni, W, Ta, Nb, Co, and Ti. In the present embodiment, an electroless Ni layer is formed as the anti-diffusion film (having a thickness of 0.1 μm) (FIG. 10). If necessary, as a process prior to formation of the electroless Ni layer, it is preferable to carry out catalytic treatment using palladium or the like on a Cu surface because an excellent reaction activity is obtained.

The anti-diffusion film may be formed in the following manner. After washing with pure water and drying by N2 blow, this substrate is introduced into a low-pressure chamber and treated in a mixed gas of WF₆, SiH₄, and Ar under an atmospheric pressure at 200° C. As a result, a reaction given by the following reaction formula is caused to occur:

WF₆+1.5SiH₄→W+1.5SiF₄+3H₂

Thus, W is selectively deposited only on the Cu surface to form the anti-diffusion film. WF₆ has a decomposition temperature of 1,000° C. but has a characteristic that, in presence of hydrogen, it is decomposed at a low temperature (even at room temperature). By utilizing the characteristic, it is possible to deposit W only on Cu at a low temperature of approximately 200° C. A silane gas SiH₄ carried by a carrier gas H₂ is decomposed only on the Cu surface at approximately 180° C. to generate hydrogen radicals. The hydrogen radicals severely reacts with F of the WF₆ gas to decompose WF₆. Therefore, W is deposited on the Cu surface. Hydrogen having reacted with F is released in the form of HF. Si is not adhered. Thus, film formation is carried out until a surface of the deposited film has a height generally same as that of the transparent resin film 11 to thereby form the wiring metal anti-diffusion layer.

By the above-mentioned process, the gate electrode of the TFT is selectively formed in the groove formed on the glass substrate by patterning of the transparent resin film 13. According to this method, the gate electrode and a gate wring may simultaneously be prepared as a pattern of the transparent resin and, therefore, this method can be used in order to manufacture the gate wiring also. Further, in case where only a wiring is formed and the substrate is used as a wiring board, the effect of the present invention can be obtained also. In case where the substrate is used alone as the wiring board, the anti-diffusion film may not be formed. In this case, it is preferable that a surface of a plating metal has a height generally same as that of a surface of the transparent resin film by adjusting a plating time.

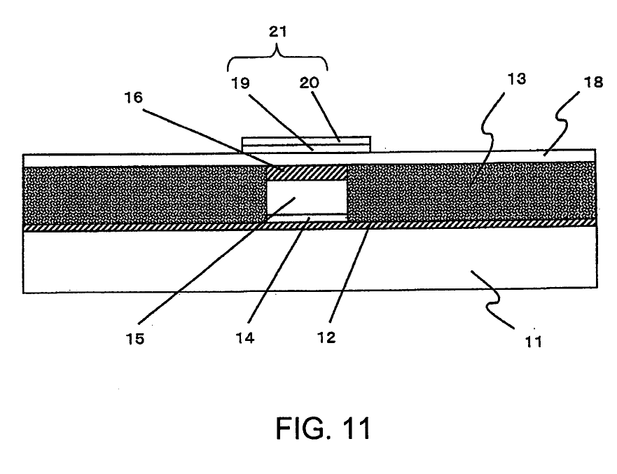

Next, by a known PECVD, a silicon nitride film as the gate insulating film 18 is formed on the wiring metal anti-diffusion layer. Further, as the semiconductor layer, a semiconductor layer amorphous silicon film 19 and an n⁺-type amorphous silicon film 20 are continuously deposited. By photolithography and known RIE, the semiconductor layer amorphous silicon film 19 and the n⁺-type amorphous silicon film 20 are partly removed to form the semiconductor layer 21 (FIG. 11).

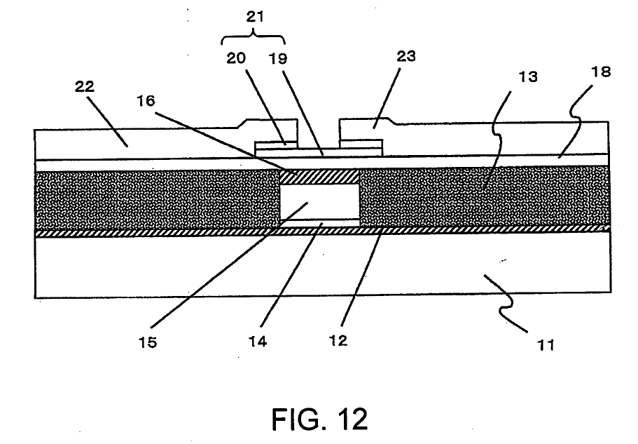

Subsequently, for the purpose of forming the source electrode 22 and the drain electrode 23, Ti, Al, and Ti are formed in this order by known sputtering or the like. Then, patterning is carried out by photolithography to form the source electrode and the drain electrode. Next, using as a mask the source electrode and the drain electrode thus formed, the n⁺-type amorphous silicon film is etched by a known technique to separate a source region and a drain region (FIG. 12). Next, by known PECVD, a silicon nitride film is formed as a protection film. Thus, the thin film transistor of the present invention is completed.

Further, a reference example of the present invention will be described. After curing of the transparent resin film 13 described in the embodiment (FIG. 7), the surface of the transparent resin film 13 is fluorinated. As fluorination, treatment is performed at 130° C. for 3 minutes in an F₂ gas atmosphere (5 vol %) under an atmospheric pressure (N₂ dilution). The surface of the transparent resin film 13 is fluorinated to enhance a hydrophobic property of the surface of the transparent resin film. Therefore, anomalous deposition of the catalyst (palladium) due to impurities on a resist surface is suppressed and a fabrication yield is improved.

### Second Embodiment

In the method of manufacturing a thin film transistor described in the first embodiment, the insulating substrate was coated with a nonphotosensitive base resin and subjected to cure baking at 150° C. for 90 seconds to form a nonphotosensitive base resin film. Subsequently, the insulating substrate was dipped for 20 minutes into a container in which ozone-added pure water having a concentration of 5 ppm was flowing, thereby oxidizing a surface of the base resin. The cure baking is carried out preferably at 80° C. to 300° C., more preferably at 100° C. to 250° C. In case where a curing temperature is low, a problem is caused to occur such that an unreacted resin component remains to degrade chemical resistance. To the contrary, in case where the curing temperature is higher than the above-mentioned range, a problem is caused to occur such that transparency is lost. The ozone-added pure water has an ozone concentration which is preferably 1 ppm to 100 ppm, more preferably 5 ppm to 50 ppm. The ozone concentration lower than this range is not preferable because plating is not deposited. The ozone concentration higher than this range is not preferable because a peeling phenomenon of the resin film and the plating film occurs due to excess oxidation of the base resin. Next, the insulating substrate was dipped into a 0.1 to 5 vol % silane coupling agent (aminopropyltriethoxysilane: KBE903 manufactured by Shin-Etsu Chemical Co., Ltd.) at 30 to 60° C. for 1 to 5 minutes, washed with water, dried, and heat-treated. Thus, the resin surface was uniformly provided with a functional group possessed by a metal coordination site. As the functional group possessed by the metal coordination site of the silane coupling agent used in the present embodiment, a carboxyl group, a sulfonate group, a mercapto group, an amino group, an imino group, an ether group, a ketone group, a thiol group, an imidazole group and so on are preferable. Among them, the silane coupling agent having the amino group is preferable in view of handling or the like. In the present embodiment, the concentration of the silane coupling agent is 1.0 vol %, a treatment temperature is 30° C., and a treating time is 1 minute. However, within the above-mentioned ranges, suitable adhesion can be obtained. As the concentration of the silane coupling agent increases, the probability of molecule collision to a base material surface increases so that, even if the treating time is short, equivalent performance can be obtained. However, the concentration higher than the above-mentioned range is not preferable because condensation between the silane coupling agents is easy to occur in a chemical solution to shorten a life of the chemical solution. On the other hand, the concentration lower than the above-mentioned range is not preferable in view of a manufacturing process because the treating time is as long as several tens of hours. Meanwhile, the temperature higher than the above-mentioned range is not preferable because condensation reaction between the silane coupling agents is easy to occur to shorten a life of the chemical solution. The temperature lower than the above-mentioned range is not preferable in view of the manufacturing process because reactivity with the base material surface is remarkably degraded and the treating time is as long as several tens of hours.

The substrate obtained as mentioned above was thereafter subjected to processes similar to those of the first embodiment. Consequently, a gate electrode of a TFT was selectively formed in a groove formed on the glass substrate by patterning of the transparent resin. Thus, the thin-film transistor was finally completed (FIG. 12).

### Third Embodiment

In a manner similar to that of the second embodiment, a transparent base resin film was formed. Thereafter, the substrate was dipped into a mixed solution containing a 6 vol % hydrogen peroxide solution as an oxidizing agent and a 80 vol % sulfuric acid at room temperature for 1 minute to modify a surface of the base resin.

Next, the substrate was dipped into a 1.0 vol % silane coupling agent (aminopropyltriethoxysilane) at room temperature for 2 minutes and subjected to washing, drying, and heat treatment. Thus, the silane coupling agent was condensed to the resin surface. By the treatment mentioned above, it is possible to reduce a time for oxidation of the transparent base resin layer and to condense the silane coupling agent to the substrate at room temperature. Thus, reduction in manufacturing time could be accomplished.

The substrate obtained as mentioned above was thereafter subjected to processes similar to those of the first embodiment. Consequently, a gate electrode of a TFT was selectively formed in a groove formed on the glass substrate by patterning of the transparent resin. Thus, the thin-film transistor was finally completed (FIG. 12).

### Fourth Embodiment

A glass substrate was washed with a mixed solution containing a 6 vol % hydrogen peroxide solution and a 80 vol % sulfuric acid for 6 minutes, thereafter washed with pure water, and dried to remove contamination of a surface of the substrate (FIG. 4).

Next, the glass substrate was subjected to steam treatment using hexamethyldisilazane, thereafter uniformly coated with a transparent resin to be a base to a thickness of 0.5 μm by using a spin coater, and subjected to baking at 100° C. (FIG. 5).

Next, the glass substrate was dipped for 10 minutes into a container in which ozone water having a concentration of 8 ppm was flowing, thereby modifing a surface of the base resin.

Next, the substrate was dipped into a 2 vol % silane coupling agent manufactured by Shin-Etsu Chemical Co., Ltd. at 50° C. for 2 minutes, and subjected to washing, drying, and heat treatment. Thus, the resin surface was uniformly provided with a functional group possessed by a metal coordination site.

After the photosensitive transparent resin film was formed as shown in FIG. 6, a mixed light of g, h, and i rays was selectively irradiated onto the photosensitive transparent resin film through a mask pattern by the use of a mask aligner. Subsequently, development was performed for 90 seconds using a 0.3 wt % tetramethylammonium hydroxide aqueous solution and thereafter rinsing was carried out for 60 seconds using pure water. Thus, a groove having a predetermined pattern was formed on the glass substrate. Subsequently, heat treatment was carried out in a nitrogen atmosphere at 230° C. for 60 minutes to cure the photosensitive transparent resin film (FIG. 7).

The substrate obtained as mentioned above was dipped into a palladium providing agent (Japan Kanigen Co., Ltd.) at room temperature for 3 minutes, treated with a reducing agent (Reducer MAB-2 manufactured by C. Uyemura & Co., Ltd.), and washed with water. As a result, a palladium catalyst was selectively provided in the groove formed as mentioned above (FIG. 8).

The substrate thus obtained was dipped into an electroless copper plating solution (PGT manufactured by C. Uyemura & Co., Ltd.) to selectively form a copper wiring in the above-mentioned groove (FIG. 9). Preferably, this process is completed at a position where the copper wiring is lower than a surface height of the photosensitive transparent resin by a film thickness of an anti-diffusion film to be subsequently formed.

In the state of FIG. 9, washing with pure water and drying by N2 blow were carried out. Thereafter, a Ni layer was formed by electroless Ni or electrolysis Ni plating with the deposited Cu film as a base, thereby forming the anti-diffusion film (FIG. 10).

By the above-mentioned process, a gate electrode of a TFT was selectively formed in the groove formed on the glass substrate by patterning of the transparent resin. Subsequently, the thin-film transistor of the present invention was finally completed in a manner similar to that of the first embodiment (FIG. 12).

The electronic devices, in particular, the thin-film transistor and the wiring board, which can be manufactured according to the present invention are suitably used in manufacturing various display devices, such as a liquid crystal display device, an organic EL display device, and an inorganic EL display device. These display devices can be manufactured by known techniques. Therefore, as one embodiment of the present invention, a method of manufacturing the liquid crystal display device or the EL display device is provided, which is characterized by using the above-mentioned method of manufacturing an electronic device according to the present invention.

### INDUSTRIAL APPLICATION FIELD

The present invention is applicable to the display device, such as the liquid crystal display device, the organic EL display device, and the inorganic EL display device, and can increase the size of these display devices. In addition, the present invention is applicable also to a wiring other than the display devices.

1. A thin-film transistor having a gate electrode on an insulating substrate, the thin-film transistor at least comprising a semiconductor layer disposed on the gate electrode through a gate insulating film on the side opposite to the insulating substrate and a source electrode and a drain electrode connected to the semiconductor layer, the thin-film transistor being variable in amount of electric current flowing between the source electrode and the drain electrode in response to a current control signal supplied to the gate electrode, wherein the gate electrode comprises an adhesive base layer, a catalyst layer, a wiring metal layer, and a wiring metal anti-diffusion layer which are laminated in this order from the insulating substrate toward the gate insulating film, the adhesive base layer being formed by a resin having a structure capable of coordinating to a metal.

2. The thin-film transistor as claimed in claim 1, wherein the gate electrode is buried in a groove formed in a planarizing layer generally flush with a surface of the gate electrode.

3. The thin-film transistor as claimed in claim 2, wherein the insulating substrate is a transparent glass substrate or a transparent resin substrate and the planarizing layer is a transparent resin layer.

4. The thin-film transistor as claimed in claim 1, wherein the catalyst layer is formed only on a portion of the gate electrode.

5. The thin-film transistor as claimed in claim 3, wherein the transparent resin layer includes one or more kinds of resins selected from a group consisting of an acrylic resin, a silicone-based resin, a fluorine-based resin, a polyimide-based resin, a polyolefin-based resin, an alicyclic olefin-based resin, and an epoxy-based resin.

6. The thin-film transistor as claimed in claim 3, wherein the transparent resin layer is formed by a photosensitive resin composition containing an alkali-soluble alicyclic olefin-based resin and a radiation-sensitive component.

7. The thin-film transistor as claimed in claim 1, wherein the resin having a structure capable of coordinating to a metal is obtained by impregnating a resin with a processing agent having a polar group or a heterocyclic compound having a metal coordinating ability.

8. The thin-film transistor as claimed in claim 7, wherein the heterocyclic compound has a functional group capable of coordinating to a metal.

9. The thin-film transistor as claimed in claim 7, wherein the heterocyclic compound is at least one kind selected from a group consisting of pyrroles, pyrrolines, pyrrolidines, pyrazoles, pyrazolines, pyrazolidines, imidazoles, imidazolines, triazoles, tetrazoles, pyridines, piperidines, pyridazines, pyrimidines, pyrazines, piperazines, triazines, tetrazines, indoles, isoindoles, indazoles, purines, norharmanes, perimidines, quinolines, isoquinolines, cinnolines, quinoxalines, quinazolines, naphthyridines, pteridines, carbazoles, acridines, phenazines, phenanthridines, phenanthrolines, furans, dioxolans, pyrans, dioxanes, benzofurans, isobenzofurans, coumarins, dibenzofurans, flavones, trithianes, thiophenes, benzothiophenes, isobenzothiophenes, dithiins, thianthrenes, thienothiophenes, oxazoles, isoxazoles, oxadiazoles, oxazines, morpholines, thiazoles, isothiazoles, thiadiazoles, thiazines, phenothiazines.

10. A wiring board having a wiring on an insulating substrate, wherein the wiring board having a sectional structure including a partial structure comprising an adhesive base layer, a catalyst layer, a wiring metal layer, and a wiring metal anti-diffusion layer which are laminated in this order from the insulating substrate toward a side where the wiring is formed, the adhesive base layer being formed by a resin having a structure capable of coordinating to a metal.

11. The wiring board as claimed in claim 10, wherein the wiring is buried in a groove formed in a planarizing layer generally flush with the wiring.

12. The wiring board as claimed in claim 11, wherein the insulating substrate is a transparent glass substrate or a transparent resin substrate and the planarizing layer is a transparent resin layer.

13. The wiring board as claimed in claim 10, wherein the catalyst layer is formed only in the partial structure.

14. The wiring board as claimed in claim 12, wherein the transparent resin layer includes one or more kinds of resins selected from a group consisting of an acrylic resin, a silicone-based resin, a fluorine-based resin, a polyimide-based resin, a polyolefin-based resin, an alicyclic olefin-based resin, and an epoxy-based resin.

15. The wiring board as claimed in claim 12, wherein the transparent resin layer is formed by a photosensitive resin composition containing an alkali-soluble alicyclic olefin-based resin and a radiation-sensitive component.

16. A display device manufactured by using the thin-film transistor claimed in claim 1.

17. The display device as claimed in claim 16, wherein the display device is a liquid crystal display device or an EL display device.

18. The display device manufactured by using the wiring board claimed in claim 10.

19. The display device as claimed in claim 18, wherein the display device is a liquid crystal display device or an EL display device.

20. A method of manufacturing an electronic device, at least including the steps of forming, on an insulating substrate, a nonphotosensitive transparent resin film having a functional group capable of coordinating to a metal at least on its surface; forming a photosensitive resin film; forming a concave portion for burying an electrode or a wiring by patterning the photosensitive resin film; providing a catalyst to the concave portion; heat curing the resin film; and forming a conductive material layer in the concave portion by plating.

21. The method of manufacturing an electronic device as claimed in claim 20, wherein the catalyst for use in the catalyst providing step contains copper, silver, palladium, platinum, nickel, zinc, or cobalt.

22. The method of manufacturing an electronic device as claimed in claim 20, further including a step of heat-treating the conductive material layer formed in the concave portion by plating.

23. The method of manufacturing an electronic device as claimed in claim 20, wherein the heat curing of the photosensitive resin film is carried out in an inert gas atmosphere or a reductive gas atmosphere.

24. The method of manufacturing an electronic device as claimed in claim 20, wherein the catalyst providing step is carried out by any one of dipping, puddling, vapor-deposition, spraying, coating, and printing.

25. The method of manufacturing an electronic device as claimed in claim 20, further including a step of forming an anti-diffusion film on a surface of the conductive material layer by CVD or plating.

26. A method of manufacturing an electronic device, at least including the steps of forming a film by using a nonphotosensitive transparent resin on an insulating substrate; carrying out preprocessing on a resultant nonphotosensitive transparent resin layer; forming a photosensitive resin film; forming a concave portion for burying an electrode or a wiring by patterning the photosensitive resin film; heat curing the resin film; providing a catalyst to the concave portion; forming a conductive material layer in the concave portion by plating; and selectively forming a conductive material anti-diffusion film on the conductive material layer.

27. The method of manufacturing an electronic device as claimed in claim 26, wherein the step of carrying out preprocessing on the nonphotosensitive transparent resin layer includes a step of impregnating the nonphotosensitive transparent resin layer with an adhesion processing agent having a functional group capable of coordinating to a metal.

28. The method of manufacturing an electronic device as claimed in claim 27, wherein the step of impregnating with the adhesion processing agent is carried out by any one of dipping, puddling, vapor-deposition, spraying, coating, and printing.

29. The method of manufacturing an electronic device as claimed in claim 27, wherein the step of carrying out preprocessing on the nonphotosensitive transparent resin layer further includes a step of slight-etching a surface of the nonphotosensitive transparent resin layer after the step of impregnating with the adhesion processing agent.

30. The method of manufacturing an electronic device as claimed in claim 27, at least including a step of using a silane coupling agent as the adhesion processing agent.

31. The method of manufacturing an electronic device as claimed in claim 30, wherein the silane coupling agent provides a resin surface with a functional group capable of coordinating to a metal.

32. The method of manufacturing an electronic device as claimed in claim 31, wherein the functional group is at least one kind selected from an amino group, a mercapto group, an ureido group, and an isocyanate group.

33. The method of manufacturing an electronic device as claimed in claim 26, wherein the step of carrying out preprocessing on the nonphotosensitive transparent resin layer includes a step of oxidizing or roughening a surface of the nonphotosensitive transparent resin layer by using water containing ozone at a concentration not lower than 1 ppm.

34. The method of manufacturing an electronic device as claimed in claim 33, wherein the ozone concentration is 5 ppm to 50 ppm.

35. The method of manufacturing an electronic device as claimed in claim 26, wherein the step of carrying out preprocessing on the nonphotosensitive transparent resin layer includes a step of oxidizing or roughening a surface of the nonphotosensitive transparent resin layer by performing heat treatment, UV treatment, or plasma treatment in a gas containing an oxygen element.

36. The method of manufacturing an electronic device as claimed in claim 26, wherein the step of carrying out preprocessing on the nonphotosensitive transparent resin layer includes a step of nitriding or roughening a surface of the nonphotosensitive transparent resin layer by performing heat treatment or plasma treatment in a gas containing a nitrogen element.

37. The method of manufacturing an electronic device as claimed in claim 26, wherein the step of carrying out preprocessing on the nonphotosensitive transparent resin layer includes a step of providing a surface of the nonphotosensitive transparent resin layer with a metal or a functional group capable of coordinating to a metal by performing heat treatment or plasma treatment.

38. The method of manufacturing an electronic device as claimed in claim 26, wherein the step of carrying out preprocessing on the nonphotosensitive transparent resin layer includes a step of oxidizing or roughening a surface of the nonphotosensitive transparent resin layer by using an oxidizing agent.

39. The method of manufacturing an electronic device as claimed in claim 26, wherein the step of carrying out preprocessing on the nonphotosensitive transparent resin layer includes a step of nitriding or roughening a surface of the nonphotosensitive transparent resin layer by using a solution containing a nitrogen element.

40. The method of manufacturing an electronic device as claimed in claim 26, wherein the step of carrying out preprocessing on the nonphotosensitive transparent resin layer includes a step of etching a surface of the nonphotosensitive transparent resin layer.

41. The method of manufacturing an electronic device as claimed in claim 26, wherein the step of carrying out preprocessing on the nonphotosensitive transparent resin layer includes a step of oxidizing, nitriding, or roughening a surface of the nonphotosensitive transparent resin layer and a step of thereafter impregnating the nonphotosensitive transparent resin layer with an adhesion processing agent having a functional group capable of coordinating to a metal.

42. The method of manufacturing an electronic device as claimed in claim 26, wherein the step of carrying out preprocessing on the nonphotosensitive transparent resin layer includes a step of introducing a hydroxyl group to a surface of the nonphotosensitive transparent resin layer and a step of condensing an adhesion agent having a functional group capable of coordinating to a metal and a hydroxyl group.

43. The method of manufacturing an electronic device as claimed in claim 42, wherein the adhesion agent having the functional group capable of coordinating to a metal and a hydroxyl group is selected from silane coupling agents which have a silanol group and a carboxyl group, a sulfonate group, a mercapto group, an amino group, an imino group, an ether group, a ketone group, a thiol group, or an imidazole group or which exhibit a function equivalent to the above-mentioned groups by hydrolysis.

44. The method of manufacturing an electronic device as claimed in claim 42, wherein the step of introducing a hydroxyl group to the surface of the nonphotosensitive transparent resin layer is performed by oxidation.

45. The method of manufacturing an electronic device as claimed in claim 44, wherein the step of performing oxidation is carried out by using any one of ozone-added pure water, a mixed aqueous solution containing a sulfuric acid and a hydrogen peroxide solution, and ultraviolet radiation.

46. The method of manufacturing an electronic device as claimed in claim 27, wherein the catalyst for use in the catalyst providing step contains copper, silver, palladium, platinum, nickel, zinc, or cobalt.

47. The method of manufacturing an electronic device as claimed in claim 27, further including a step of heat-treating the conductive material layer formed in the concave portion by plating.

48. The method of manufacturing an electronic device as claimed in claim 27, wherein the heat curing of the photosensitive resin film is carried out in an inert gas atmosphere or in a reductive gas atmosphere.

49. The method of manufacturing an electronic device as claimed in claim 27, wherein the catalyst providing step is carried out by any one of dipping, puddling, vapor-deposition, spraying, coating, and printing.

50. The method of manufacturing an electronic device as claimed in claim 27, wherein the anti-diffusion film is formed by electroless plating or electrolysis plating containing a metal selected from Ni, W, Ta, Nb, Co, and Ti, or by chemical vapor deposition using a fluoride gas containing the above-mentioned metal element as a material.

51. The method of manufacturing an electronic device as claimed in claim 50, further including a step of nitriding by nitrogen plasma a surface of the anti-diffusion film formed as mentioned above.

52. The method of manufacturing an electronic device as claimed in claim 20, wherein the electronic device is a thin-film transistor or a wiring board.

53. A method of manufacturing a liquid crystal display device wherein the display device is formed by using the method claimed in claim 20.

54. The method of manufacturing an electronic device as claimed in claim 26, wherein the electronic device is a thin-film transistor or a wiring board.

55. A method of manufacturing a liquid crystal display device, wherein the display device is formed by using the method claimed in claim 26.

56. A method of manufacturing an EL display device, wherein the display device is formed by using the method claimed in claim 20.

57. A method of manufacturing an EL display device, wherein the display device is formed by using the method claimed in claim 26.
